(19) United States
(12) Patent Application Publication
(10) Pub. No.: US 2002/0149055 A1
(43) Pub. Date: Oct. 17, 2002

(54) Semiconductor device including insulating substrate formed of single-crystal silicon chip

(75) Inventor: Yoshifumi Tomomatsu, Fukuoka (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: Mitsubishi Denki Kabushiki Kaisha, Tokyo (JP)

(21) Appl. No.: 09/971,615

(22) Filed: Oct. 9, 2001

(30) Foreign Application Priority Data
Apr. 11, 2001 (JP) 2001-112800

(51) Int. Cl. H01L 27/01

(52) U.S. Cl. 257/350

(57) ABSTRACT

A semiconductor device includes an insulating substrate for electrical insulation formed of a single-crystal silicon chip as a base, an electrode pattern formed on the insulating substrate to allow electric current to pass therethrough, and a plurality of semiconductor elements selectively mounted on the electrode pattern. The plurality of semiconductor elements and the electrode pattern are selectively electrically connected to each other.

### BACKGROUND OF THE INVENTION

1. Field of the Invention

The present invention relates to a power semiconductor device or power module having an enhanced heat-radiating performance and capable of relatively easily ensuring the desired dielectric strength.

2. Description of the Related Art

It is an important parameter for power semiconductors to sufficiently ensure the heat-radiating performance, because the power semiconductors deal with a large amount of power.

FIGS. 9 and 10 depict a conventional ordinary power module wherein an insulating substrate 54 is placed on a metallic base plate 52 that is intended for enhancing the hear-radiating performance. The insulating substrate 54 has two metallic electrode patterns 56, 58 formed on opposite surfaces thereof, respectively. The electrode pattern 56 on one surface of the insulating substrate 54 has IGBTs (Insulated Gate Bipolar Transistors) 60 and diode chips 62 mounted thereon, which are electrically connected to the electrode pattern 56 by wire bonding or the like. Two electrodes 64 extend outwardly from the electrode pattern 56.

This power module generally has a casing to enhance the airtightness, which is omitted from FIGS. 9 and 10 so that the internal construction thereof can be readily explained.

FIG. 11 depicts a typical example of an equivalent circuit offered by the power module of FIGS. 9 and 10.

The greatest advantage of the illustrated power module is ensuring the insulation inside it, and such insulation is achieved by the use of alumina (Al₂O₃), aluminum nitride (AIN) or the like.

With reference to FIGS. 12A and 12B, the insulating substrate 54 is further discussed.

The metallic films (the above-described metallic patterns) 56, 58 are formed on the opposite surfaces of the insulating substrate 54. The metallic films 56 on the front surface of the insulating substrate 54 form respective electrodes to allow required electric current to pass therethrough, while the metallic film 58 on the rear surface of the insulating substrate 54 has a function of bonding the insulating substrate 54 to the metallic base plate 52.

Where alumina is used for the insulating substrate 54 of the above-described construction, the low heat conductivity (about 23 W/mK) exhibited by alumina poses a problem. Although this problem can be overcome to some extent by reducing the thickness of alumina itself, there arises another problem that the mechanical strength reduces or a leakage current is caused by an increase in capacity formed between the electrodes on the front surface of the insulating substrate 54 and the metallic base plate 52.

On the other hand, the use of aluminum nitride is free from the problem associated with alumina, because it has a very high heat conductivity (about 130 W/mK). Alumina nitride is, however, relatively costly.

In view of the problem inherent in the conventional method associated with the formation of a coating on heat-sensitive devices or other substrates, Japanese Laid-open Patent Publication No. 7-25606 discloses the formation of a thin and lightweight ceramic coating on a substrate. According to this publication, the ceramic coating is formed on the substrate at a temperature below about 400° C. This publication is, however, silent about the heat conductivity, mechanical strength, cost and the like of the substrate.

### SUMMARY OF THE INVENTION

The present invention has been developed to overcome the above-described disadvantages.

It is accordingly an objective of the present invention to provide a semiconductor device having a relatively high heat conductivity and capable of ensuring a sufficient mechanical strength and required electrical insulation.

Another objective of the present invention is to provide the semiconductor device of the above-described type which can be manufactured at a low cost.

In accomplishing the above and other objectives, the semiconductor device according to the present invention includes an insulating substrate for electrical insulation formed of a single-crystal silicon chip as a base, an electrode pattern formed on the insulating substrate to allow electric current to pass therethrough, and a plurality of semiconductor elements selectively mounted on the electrode pattern. The plurality of semiconductor elements and the electrode pattern are selectively electrically connected to each other.

The use of the single-crystal silicon chip for the insulating substrate makes it possible to maintain the heat conductivity at a relatively high value (about 84 W/mK) and ensure a sufficient mechanical strength, compared with the case where alumina is used. Further, as similar to the conventional semiconductor chips, the insulating substrate can be manufactured using a single-crystal wafer. This offers inexpensive semiconductor devices, compared with the case where aluminum nitride is used.

The insulating substrate may be formed on a metallic base plate for heat radiation. By so doing, the present invention is applicable to a semiconductor device having such a metallic base plate.

Advantageously, an insulating layer is formed on at least one surface of the insulating substrate to ensure required electrical insulation.

Two insulating layers may be formed on opposite surfaces of the insulating substrate, respectively, thereby further enhancing the electrical insulating properties.

Conveniently, the insulating layer is made of silicon dioxide. With this construction, the insulating layer can be formed merely by oxidizing the insulating substrate, making it possible to provide inexpensive semiconductor devices.

Advantageously, the electrode pattern is formed on one surface of the insulating layer. The insulating layer acts to ensure the required electrical insulation.

An auxiliary electrode may be mounted on the electrode pattern. The auxiliary electrode acts to reduce the voltage drop across and the size of a power module.

In that case, it is preferred that the auxiliary electrode be made of a wire bond or metallic piece. The use of the wire bond or metallic piece makes it possible to manufacture the semiconductor devices at a low cost.

### BRIEF DESCRIPTION OF THE DRAWINGS

The above and other objectives and features of the present invention will become more apparent from the following description of a preferred embodiment thereof with reference to the accompanying drawings, throughout which like parts are designated by like reference numerals, and wherein:

FIG. 1 is a front view of an insulating substrate according to a first embodiment of the present invention;

FIG. 2 is a cross-sectional view taken along line II-II in FIG. 1;

FIG. 3 is a front view of a power module employing the insulating substrate of FIG. 1;

FIG. 4 is a cross-sectional view of the power module of FIG. 3;

FIGS. 5A, 5B, 5C, 5D, 5E and 5F are schematic views depicting a series of processes of manufacturing the insulating substrate of FIG. 1 and particularly depicting a manufacturing method according to a third embodiment of the present invention;

FIGS. 6A, 6B, 6C, 6D, 6E, 6F, 6G and 6H are schematic views depicting a series of processes of manufacturing the insulating substrate of FIG. 4 and particularly depicting a manufacturing method according to a fourth embodiment of the present invention;

FIG. 7 is a front view of a power module according to a fifth embodiment of the present invention;

FIG. 8 is a front view of a power module according to a sixth embodiment of the present invention;

FIG. 9 is a front view of a conventional power module;

FIG. 10 is a cross-sectional view taken along line X-X in FIG. 9;

FIG. 11 is an equivalent circuit diagram of the power module of FIG. 9;

FIG. 12A is a front view of an insulating substrate employed in the power module of FIG. 9; and

FIG. 12B is a rear view of the insulating substrate of FIG. 12A.

### DETAILED DESCRIPTION OF THE PREFERRED EMBODIMENTS

This application is based on an application No. 2001-112800 filed Apr. 11, 2001 in Japan, the content of which is herein expressly incorporated by reference in its entirety.

### EMBODIMENT 1

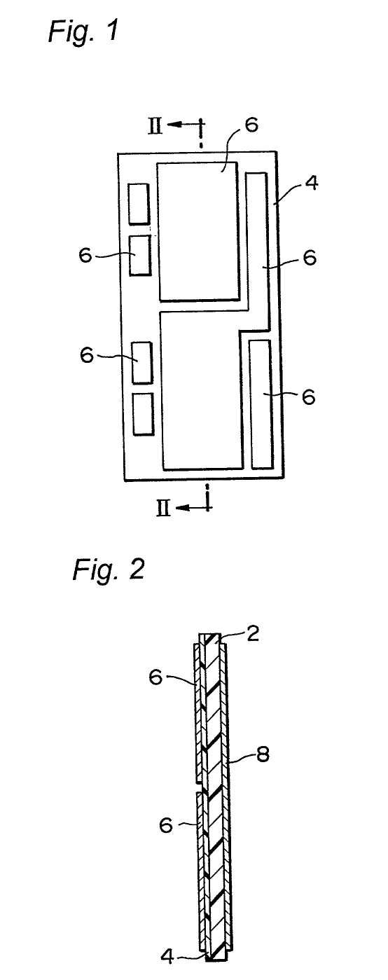

Referring now to the drawings, there is shown in FIGS. 1 and 2 an insulating substrate 2 according to a first embodiment of the present invention. The insulating substrate 2 has a metallic electrode pattern 6 formed on a front surface thereof via an insulating layer 4 to allow electric current to pass therethrough, and also has a metallic electrode pattern 8 formed on a rear surface thereof. The insulating substrate 2 for electrical insulation is formed of a single-crystal silicon chip as a base, and the provision of the insulating layer 4 on one principal surface thereof ensures the required insulation.

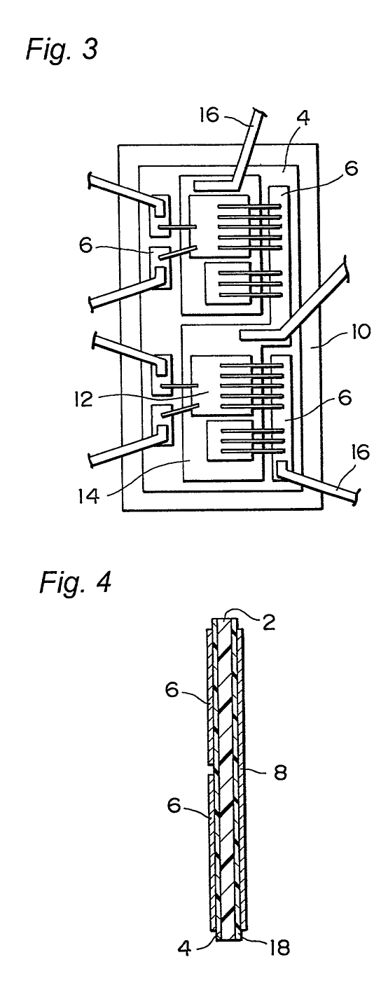

FIG. 3 depicts a power module having the insulating substrate 2 of the above-described construction. The illustrated power module includes a metallic base plate 10 for enhancing the heat-radiating performance and the insulating substrate 2 formed thereon. The insulating substrate 2 has two electrode patterns 6, 8 formed on opposite surfaces thereof, respectively. The electrode pattern 6 formed on the front surface of the insulating substrate 2 via the insulating layer 4 has semiconductor elements such, for example, as IGBTs (Insulated Gate Bipolar Transistors) 12, diode chips 14 and the like selectively mounted thereon. These elements are selectively electrically connected to the electrode pattern 6 by wire bonding or the like. Two electrodes 16 extend outwardly from the electrode pattern 6.

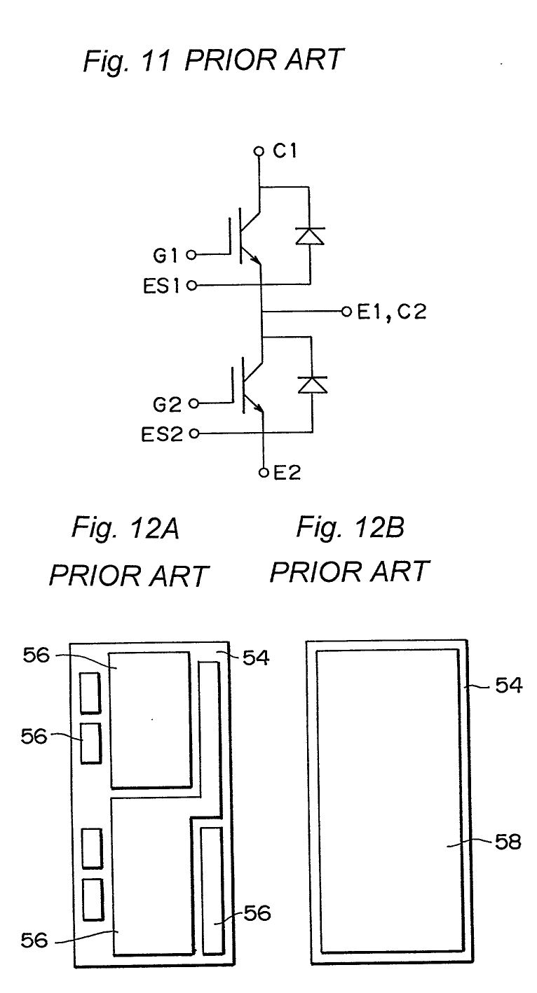

The power module has an equivalent circuit identical to that shown in FIG. 11.

### EMBODIMENT 2

FIG. 4 depicts an insulating substrate 2 according to a second embodiment of the present invention. The insulating substrate 2 shown therein has a electrode pattern 6 formed on a front surface thereof via an insulating layer 4 and an electrode pattern 8 similarly formed on a rear surface thereof via an insulating layer 18. The insulating substrate 2 is formed of a single-crystal silicon chip as a base, and the provision of the insulating layers 4, 18 on both principal surfaces thereof ensures the required insulation.

Furthermore, the insulating layers 4, 18 formed on both the principal surfaces of the insulating substrate 2 act to increase a tolerance for dielectric strength and equalize the stress produced in both the principal surfaces by the formation of the insulators, thus restraining a possible warp of the insulating substrate 2.

### EMBODIMENT 3

A method of manufacturing the insulating substrate 2 as shown in FIGS. 1 and 2 is discussed hereinafter.

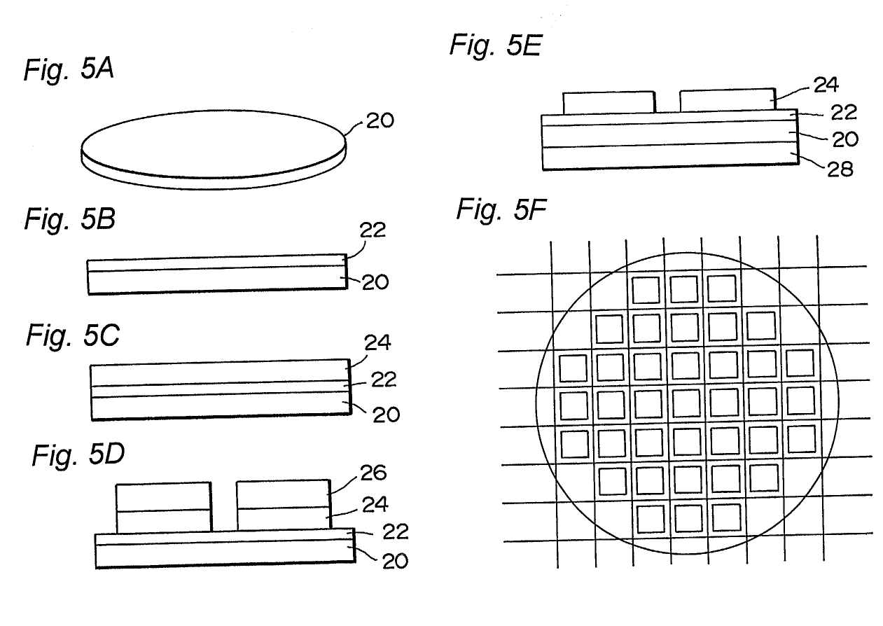

A silicon wafer 20 shown in FIG. 5A is first prepared. As shown in FIG. 5B, a silicon dioxide layer 22 is then formed on one surface of the silicon wafer 20 by, for example, the thermal oxidation method, CVD method or the like. Because the silicon dioxide layer 22 thus formed is used as the insulating film 4, the film thickness is so set as to be able to ensure the required dielectric strength.

As shown in FIG. 5C, an electrode layer 24 is then formed on the surface of the silicon dioxide layer 22 for use as the insulating film 4 by, for example, vacuum deposition, sputtering or the like. In the power module, where the insulating substrate is soldered to the metallic base plate or the semiconductor chips, it is sufficient if a plurality of metallic films such as Al/Mo/Ni/Au are formed. The total thickness of the metallic films is determined taking a voltage drop occurring when electric current flows into consideration.

Thereafter, as shown in FIG. 5D, using the photolithographic technique that is generally used in the semiconductor manufacturing process, a specific resist pattern 26 is formed on the electrode layer 24, and a desired electrode pattern 6 is then formed by removing the electrode layer 24 other than that covered with the resist pattern 26.

As shown in FIG. 5E, the resist pattern 26 used in the previous step is then removed, and an electrode layer 28 is formed on a rear surface of the silicon wafer 20 in a manner similar to the step shown in FIG. 5C.

Finally, the silicon wafer 20 is cut into a plurality of insulating substrates 2 of a predetermined shape by dicing, as shown in FIG. 5F.

### EMBODIMENT 4

A method of manufacturing the insulating substrate 2 as shown in FIG. 4 is discussed hereinafter.

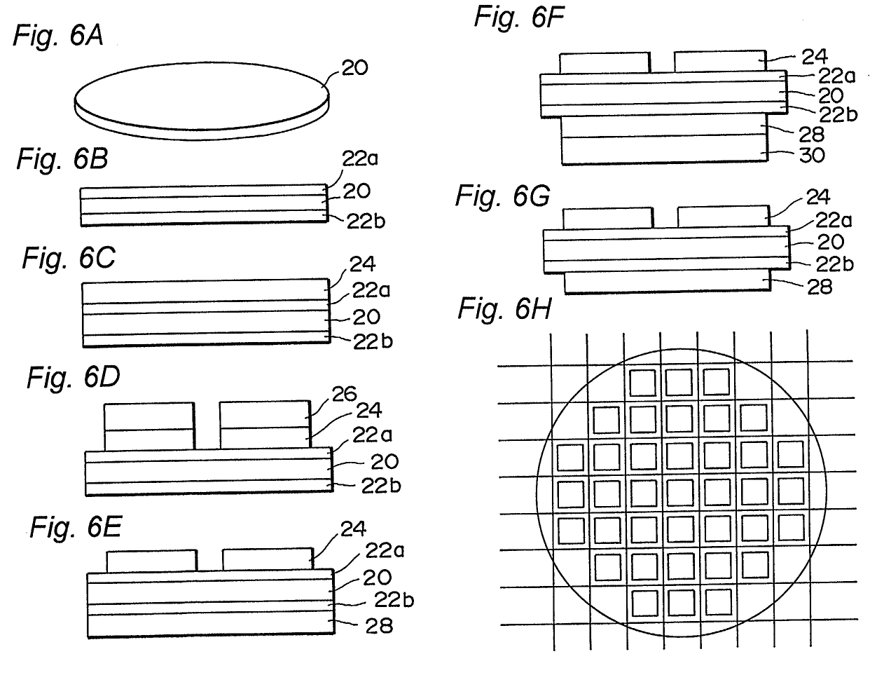

A silicon wafer 20 shown in FIG. 6A is first prepared. As shown in FIG. 6B, silicon dioxide layers 22a, 22b are then formed on opposite surfaces of the silicon wafer 20 by, for example, the thermal oxidation method, CVD method or the like. Because the silicon dioxide layers 22a, 22b thus formed are used as the insulating films 4, 18, respectively, the film thickness is so set as to be able to ensure the required dielectric strength.

As shown in FIG. 6C, an electrode layer 24 is then formed on the surface of the silicon dioxide layer 22a for use as the insulating film 4 by, for example, vacuum deposition, sputtering or the like. In the power module, where the insulating substrate is soldered to the metallic base plate or the semiconductor chips, it is sufficient if a plurality of metallic films such as Al/Mo/Ni/Au are formed. The total thickness of the metallic films is determined taking a voltage drop occurring when electric current flows into consideration.

Thereafter, as shown in FIG. 6D, using the photolithographic technique that is generally used in the semiconductor manufacturing process, a specific resist pattern 26 is formed on the electrode layer 24, and a desired electrode pattern 6 is then formed by removing the electrode layer 24 other than that covered with the resist pattern 26.

As shown in FIG. 6E, the resist pattern 26 used in the previous step is then removed, and an electrode layer 28 is formed on the surface of the silicon dioxide layer 22b in a manner similar to the step shown in FIG. 6C.

Furthermore, as shown in FIG. 6F, using the photolithographic technique that is generally used in the semiconductor manufacturing process, a specific resist pattern 30 is formed on the electrode layer 28, and a desired electrode pattern 8 is then formed by removing the electrode layer 28 other than that covered with the resist pattern 30.

Thereafter, the resist pattern 30 used at the previous step is removed, as shown in FIG. 6G.

Finally, the silicon wafer 20 is cut into a plurality of insulating substrates 2 of a predetermined shape by dicing, as shown in FIG. 6H.

### EMBODIMENT 5

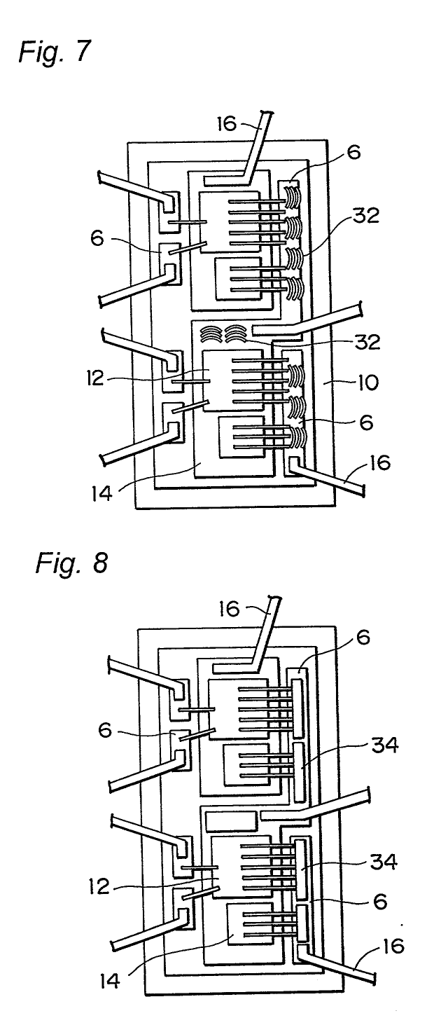

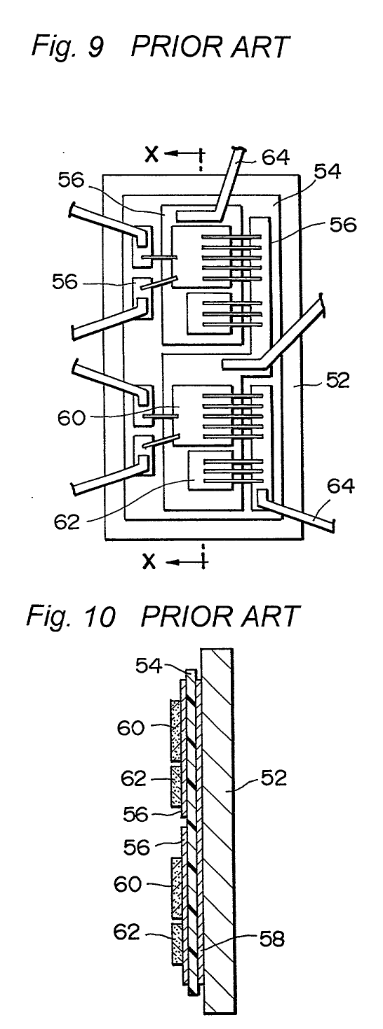

FIG. 7 depicts a power module according to a fifth embodiment of the present invention, wherein a plurality of wire bonds 32 are mounted as auxiliary electrodes on the electrode pattern 6.

Although the insulating substrate 2 can be relatively easily manufactured using the above-described processes, there are some cases where the m electrode pattern 6 cannot be so thick. In such cases, the plurality of wire bonds 32 selectively mounted on the electrode pattern 6 act to disperse electric current, making it possible to reduce the voltage drop across and the size of the power module.

### EMBODIMENT 6

FIG. 8 depicts a power module according to a sixth embodiment of the present invention, wherein a plurality of metallic pieces 34 are mounted as auxiliary electrodes on the electrode pattern 6.

As described above, If the electrode pattern 6 cannot be so thick, the plurality of metallic pieces 34 selectively joined to the electrode pattern 6 by, for example, soldering act to disperse electric current, making it possible to reduce the voltage drop across and the size of the power module.

It is to be noted here that although in the above-described embodiments a power module having a metallic base plate has been taken as a typical example, the present invention is not limited to such a power module, but is applicable to a power module having no metallic base plate.

Although the present invention has been fully described by way of examples with reference to the accompanying drawings, it is to be noted here that various changes and modifications will be apparent to those skilled in the art. Therefore, unless such changes and modifications otherwise depart from the spirit and scope of the present invention, they should be construed as being included therein.

What is claimed is:

1. A semiconductor device comprising:
an insulating substrate for electrical insulation formed of a single-crystal silicon chip as a base;
an electrode pattern formed on said insulating substrate to allow electric current to pass therethrough; and
a plurality of semiconductor elements selectively mounted on said electrode pattern;
wherein said plurality of semiconductor elements and said electrode pattern are selectively electrically connected to each other.

2. The semiconductor device according to claim 1, further comprising a metallic base plate for heat radiation, on which said insulating substrate is formed.

3. The semiconductor device according to claim 1, further comprising an insulating layer formed on at least one surface of said insulating substrate to ensure electrical insulation.

4. The semiconductor device according to claim 1, further comprising two insulating layers formed on opposite surfaces of said insulating substrate, respectively, to ensure electrical insulation.

5. The semiconductor device according to claim 3, wherein said insulating layer is made of silicon dioxide.

6. The semiconductor device according to claim 3, wherein said electrode pattern is formed on one surface of said insulating layer.

7. The semiconductor device according to claim 1, further comprising an auxiliary electrode mounted on said electrode pattern.

8. The semiconductor device according to claim 7, wherein said auxiliary electrode comprises a wire bond.

9. The semiconductor device according to claim 7, wherein said auxiliary electrode comprises a metallic piece.
